(19) United States
(12) Patent Application Publication
(10) Pub. No.: US 2010/0141458 A1
(43) Pub. Date: Jun. 10, 2010

(54) ILLUMINATED KEYBOARD AND ILLUMINATING METHOD FOR KEYBOARD

(76) Inventor: Chang-Chia Chiang, Taipei City (TW)

Correspondence Address: PATTERSON & SHERIDAN, LLP - - - IPTEC, 3040 Post Oak Boulevard, Suite 1500, Houston, TX, 77056-6582, US

(21) Appl. No.: 12/622,468

(22) Filed: Nov. 20, 2009

(30) Foreign Application Priority Data
Dec. 4, 2008 (TW) 097147141

(51) Int. Cl. G08B 17/12; H03M 11/00

(52) U.S. Cl. 340/600; 341/22; 341/33

(57) ABSTRACT

An illuminated keyboard and an illuminating method for a keyboard are disclosed. The illuminated keyboard includes an illumination module, a first sensing module, a second sensing module, and a control module. The first sensing module is used for sensing an ambient light. If the brightness of the ambient light is less then a reference brightness, the first sensing module generates a first signal. The second sensing module is used for sensing a state of touch on the illuminated keyboard and generating a second signal according to the state of touch. The control module is connected to the illumination module, the first sensing module, and the second sensing module respectively for driving the illumination module to emit light according to the first signal and the second signal.

### BACKGROUND OF THE INVENTION

1. Field of the Invention

This invention relates to an illuminated keyboard and an illuminating method for keyboard and more particularly relates to an illuminated keyboard and an illuminating method for keyboard with the advantage of power saving.

2. Description of the Prior Art

As technique develops, information industry rapidly develops recently. People may use portable information devices under different environments, such as notebook or personal digital assistant (PDA) etc. Under an environment of weak light, a user may not see the numbers or letters marked on the keys of a keyboard. It leads to the difficulty of operation, even to the damage to the vision of the user due to the forced identification on the marks on the keys. Thus, the supply of an illuminated keyboard could improve the inconvenience of using the keyboard under an environment of weak light.

The advantage of the illuminated keyboard is that a user could still identify different keys clearly through the diffused light around the keys or the light passing through the central portion of the key even under an environment of weak light. Thereby, regardless of the constraints of the ambient light, the user still could perform keying rapidly and conveniently through the illuminated keyboard when using a computer. Furthermore, besides the function of a product, the appearance of the product is also considered. By the arrangement of different lighting, an information apparatus with the illuminated keyboard looks beautiful so as to increase sales. The product with the illuminated keyboard has the potential in the market more then those without illuminated keyboards.

Recently, the consciousness of environmental protection rises rapidly. The power saving is considered more and more. Most of the illuminated keyboards in the market are made with an optical sensor disposed in the keyboard for sensing the intensity of the ambient light. If the intensity of the ambient light is sensed to be lower than a setting value, the keyboard emits light.

However, for the illuminated keyboards in the market, when the user leaves his seat or does not key through the illuminated keyboard, the illuminated keyboard still emits light according to the judgement of the insufficient ambient light. In other words, when the user is not using the illuminated keyboards which continually emit light, the electrical power is just wasted and the cost and load and of the company increases.

### SUMMARY OF THE INVENTION

The invention discloses an illuminated keyboard which includes an illumination module, a first sensing module, a second sensing module, and a control module. The first sensing module is used for sensing an ambient light. When a brightness of the ambient light is less then a reference brightness, the first sensing module generates a first signal. The second sensing module is used for sensing a state of touch on the illuminated keyboard and generating a second signal according to the state of touch. The control module is connected to the illumination module, the first sensing module, and the second sensing module respectively for driving the illumination module to emit light according to the first signal and the second signal.

In addition, the invention also discloses an illuminating method for a keyboard. The illuminating method could be applied to the keyboard with an illumination module. The illuminating method of the invention includes the following steps. First, the step (a) is performed: sensing an ambient light. Then, the step (b) is performed: judging whether a brightness of the ambient light is less then a reference brightness, and if YES, generating a first signal and performing the step (c). The step (c) is performed: judging whether a state of touch on the keyboard is sensed, and if YES, generating a second signal. At last, the step (d) is performed: driving the illumination module to emit light according to the first signal and the second signal.

Compared with the prior art, the illuminated keyboard of the invention could further judge whether the user is using the keyboard or not under an environment of weak light. Thereby, the illuminated keyboard could emit light at the right time for illumination request, so as to achieve the purpose of power saving or economy.

The advantage and spirit of the invention may be understood by the following recitations together with the appended drawings.

### BRIEF DESCRIPTION OF THE APPENDED DRAWINGS

FIG. 1 is an appearance view of an illuminated keyboard of an embodiment according to the invention.

FIG. 2 is a block diagram illustrating the main components in the illuminated keyboard in FIG. 1.

FIG. 3 is a flow chart of the illuminating method for the keyboard according to an embodiment of the invention.

### DETAILED DESCRIPTION OF THE INVENTION

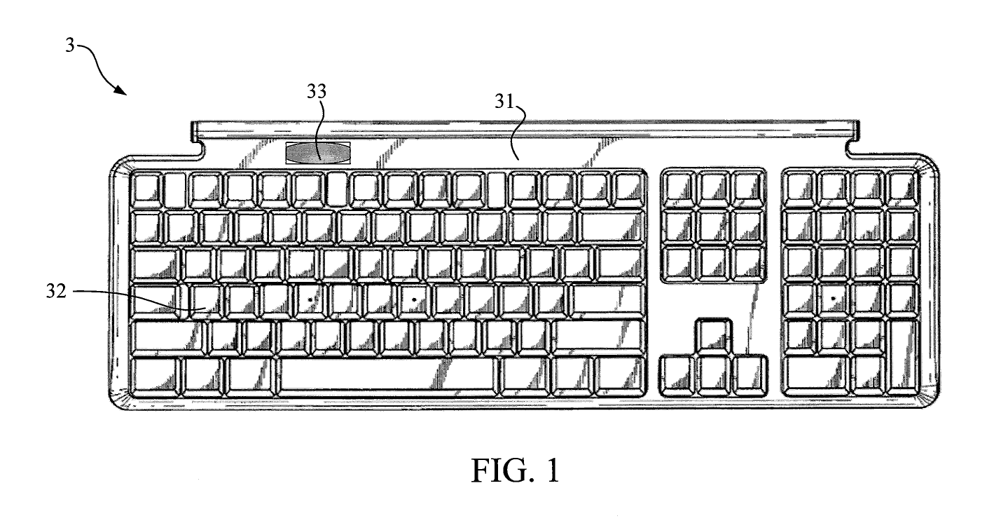

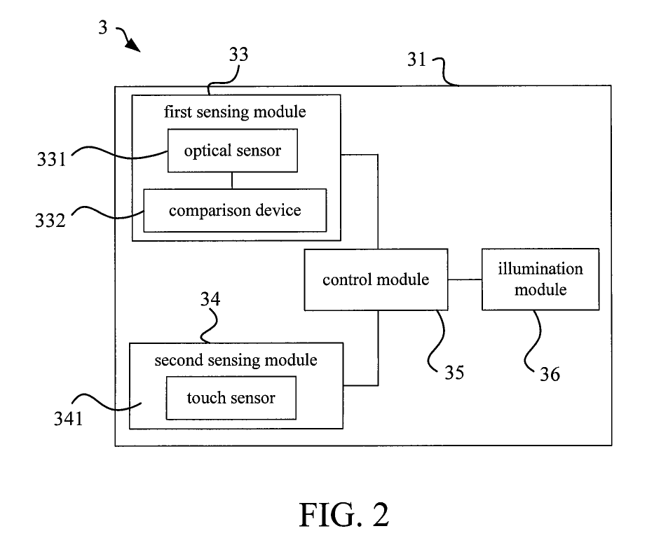

Please refer to FIGS. 1 and 2. FIG. 1 is an appearance view of an illuminated keyboard 3 of an embodiment according to the invention. FIG. 2 is a block diagram illustrating the main components in the illuminated keyboard 3 in FIG. 1. As shown in FIGS. 1 and 2, the illuminated keyboard 3 of the invention includes a casing 31, a plurality of keys 32, a first sensing module 33, a second sensing module 34, a control module 35, and an illumination module 36. The following description will introduce the illuminated keyboard 3 of the embodiment further and explain in detail, including the structure of the components therein and the function and operation thereof.

As shown in FIGS. 1 and 2, the first sensing module 33 includes an optical sensor 331 and a comparison device 332. Therein, the optical sensor 331 of the first sensing module 33 could be disposed on the surface of the casing 31 and electrically connected to the comparison device 332. Furthermore, the comparison device 332 has a user-defined reference brightness stored therein. The optical sensor 331 is used for sensing the ambient light around the illuminated keyboard 3. The comparison device 332 is used for comparing the brightness sensed by the first sensing module 33 with the reference brightness. If the brightness of the ambient light is less then the reference brightness, the comparison device 332 the first sensing module 33 generates a first signal.

Similarly in FIG. 2, the second sensing module 34 includes a touch sensor 341. The touch sensor 341 could be a capacitive touch sensor, a resistive touch sensor or other kinds of touch sensors; however, the invention is not limited to this. In other words, as long as any sensing device could sense a touch or a disposition by an object on the surface of the illuminated keyboard 3, it could be taken as the touch sensor 341 of the second sensing module 34. The second sensing module 34 is used for sensing a state of touch on the illuminated keyboard 3 and generating a second signal according to the state of touch.

Similarly in FIG. 2, the control module 35 is electrically connected to the first sensing module 33, the second sensing module 34, and the illumination module 36 respectively. The control module 35 could drive the illumination module 36 to emit light according to the first signal generated by the first sensing module 33 and the second signal generated by the second sensing module 34. In addition, the illumination module 36 could be a light source with a plurality of light-emitting diodes, but the light source is not limited to be with light-emitting diodes for illuminating. The following description is made for the invention further.

TABLE 1

| | induced current due to | | current | |
|---|---|---|---|---|
| | the sensing by the optical | reference | corresponding to the | |
| ambient light | sensor to the ambient light | brightness | reference brightness | output the |
| (lm) | (mA) | (lm) | (mA) | first signal? |
| 20 | 5 | 30 | 8 | YES |
| 40 | 10 | 30 | 8 | NO |
| 60 | 15 | 30 | 8 | NO |

As shown in the table 1 above, the table 1 shows the parameters of the ambient light sensed by the optical sensor 331 of the first sensing module 33. The reference brightness in the table 1 presents the parameter defined by the user to the comparison device 332. The reference brightness could be reset by the user under different requirements.

Furthermore, the induced current due to the sensing by the optical sensor to the ambient light presents the current induced in the optical sensor 331 because of the optical sensor 331 sensing the ambient light. Especially, the ambient light sensed by the optical sensor 331 is not limited to be transformed in form of current signals; it is acceptable to transform the sensed ambient light to any readable form, such as voltage signals. In addition, if the ambient light sensed by the optical sensor 331 is transformed in form of voltage signals, the reference brightness shown in the table 1 will be transformed into a corresponding proper voltage so as to compare the reference brightness with the current ambient light.

It is found in the table 1 that if the ambient light sensed by the optical sensor 331 of the first sensing module 33 is 20 lm, the sensed ambient light could be transformed into current of 5 mA. The current of 5 mA flows to the comparison device 332. The comparison device 332 receives the current from the optical sensor 331 and then compares the received current with the reference brightness. If the ambient light is 20 lm, the default value of the comparison device 332 is larger than the current induced in the optical sensor 331. The comparison device 332 therefore generates the first signal and transmits the first signal to the control module 35.

Furthermore, the touch sensor 341 of the second sensing module 34 performs sensing on the surface of the illuminated keyboard 3. For example, if the touch sensor 341 is a capacitive touch sensor, and a hand of the user touches the surface of the illuminated keyboard 3, the capacitive touch sensor senses the increment in the capacity of the surface of the illuminated keyboard 3. Thereby, the capacitive touch sensor transmits the second signal to the control module 35. The control module 35 then drives the light-emitting diodes in the illumination module 36 to emit light according to the first signal from the first sensing module 33 and the second signal from the second sensing module 34.

Compared with the prior art, the illuminated keyboard of the invention further judges whether the user is using the keyboard or not under an environment of weak light so that the illuminated keyboard could emit light at the right time for illumination request, so as to achieve the purpose of power saving or economy.

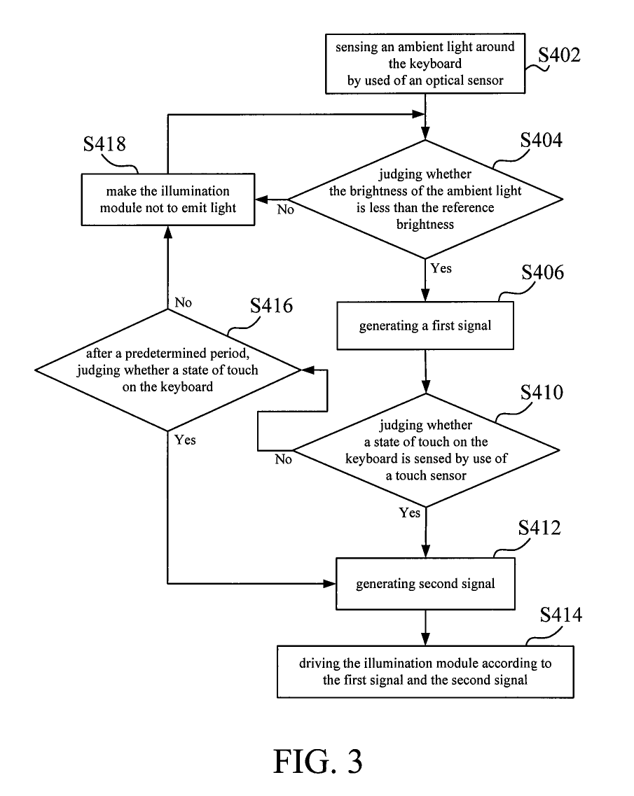

Please refer to FIG. 3. FIG. 3 is a flow chart of the illuminating method for the keyboard according to an embodiment of the invention. The illuminating method of the invention applies to the keyboard with the illumination module. The illuminating method includes the following steps.

First, the illuminating method of the invention is to perform the step S402: sensing the ambient light around the keyboard by used of the optical sensor.

Then, the illuminating method of the invention is to perform the step S404: judging whether the brightness of the ambient light is less then the reference brightness, and if YES, performing the step S406 of generating the first signal. Therein, in the step S406, the first signal is generated by the comparison device; the step S410 is then performed. If the judging in the step S404 is NO, the step S418 is performed according to the illuminating method of the invention to make the illumination module not emit light.

Next, the illuminating method of the invention is to perform the step S410: judging whether a state of touch on the keyboard is sensed by use of the touch sensor. Therein, the touch sensor could be a capacitive touch sensor or a resistive touch sensor; however, the invention is not limited to this. If the judging in the step S410 is YES, the step S412 is performed according to the illuminating method of the invention to generate the second signal. If the judging in the step S410 is NO, the step S416 is performed according to the illuminating method of the invention to judge again whether a state of touch on the keyboard is sensed. If the judging in the step S416 is YES, the step S412 is performed according to the illuminating method of the invention to generate the second signal. If the judging in the step S416 is NO, the step S418 is performed according to the illuminating method of the invention to make the illumination module not emit light.

In particular, even when the state of touch on the keyboard is positively judged in the step S410, the judging of whether a state of touch on the keyboard is sensed is performed again after a predetermined period passes. If the judging in the step S410 is YES, the step S412 is performed according to the illuminating method of the invention. If the judging in the step S410 is NO, the step S416 is performed according to the illuminating method of the invention. When the state of touch on the keyboard is positively judged in the step S410, it could avoid miss-emitting light because of careless touch on the keyboard or other objects touching the keyboard that judging again whether a state of touch on the keyboard is sensed after the predetermined period. Therefore, the situation of the keyboard emitting light just because of any accidental touch on the keyboard could be avoided, so as to make the keyboard emit light at the right time of the operation by the user.

At last, the illuminating method of the invention is to perform the step S414: driving the illumination module to emit light according to the first signal and the second signal. Therein, the illumination module could be a light source with light-emitting diodes, but the light source is not limited to be with light-emitting diodes for illuminating.

Compared with the prior art, the illuminated keyboard and the illuminating method of the invention could perform the light emitting when both the ambient light is insufficient and the confirmation of the user being operating the keyboard is made. Therefore, the illuminated keyboard and the illuminating method of the invention could make the keyboard with the illumination function emit light at the right time for illumination request, so as to achieve the purpose of power saving or economy.

With the example and explanations above, the features and spirits of the invention will be hopefully well described. Those skilled in the art will readily observe that numerous modifications and alterations of the device may be made while retaining the features and spirit of the invention. Accordingly, the above disclosure should be construed as limited only by the metes and bounds of the appended claims.

What is claimed is:

1. An illuminated keyboard, comprising:
an illumination module;
a first sensing module, for sensing an ambient light, when a brightness of the ambient light is less then a reference brightness, the first sensing module generating a first signal;
a second sensing module, for sensing a state of touch on the illuminated keyboard and generating a second signal according to the state of touch; and
a control module, connected to the illumination module, the first sensing module, and the second sensing module respectively for driving the illumination module to emit light according to the first signal and the second signal.

2. The illuminated keyboard of claim 1, wherein the first sensing module comprises:
an optical sensor, for sensing the ambient light; and
a comparison device, electrically connected to the light sensor, when the brightness of the ambient light is less then the reference brightness, the comparison device generating the first signal.

3. The illuminated keyboard of claim 1, wherein the second sensing module comprises a capacitive touch sensor.

4. The illuminated keyboard of claim 1, wherein the second sensing module comprises a resistive touch sensor.

5. The illuminated keyboard of claim 1, wherein the illumination module comprises a light-emitting diode.

6. An illuminating method for a keyboard, the keyboard comprising an illumination module, the illuminating method comprising the following steps of:
(a) sensing an ambient light;
(b) judging whether a brightness of the ambient light is less then a reference brightness, and if YES, generating a first signal and performing step (c);
(c) judging whether a state of touch on the keyboard is sensed, and if YES, generating a second signal; and
(d) driving the illumination module to emit light according to the first signal and the second signal.

7. The illuminating method of claim 6, wherein if the judging in the step (c) is NO, the illuminating method further comprises the following steps of:
(c1) after a predetermined period passes, judging again whether a state of touch on the keyboard is sensed, and if YES, generating a second signal.

8. The illuminating method of claim 6, wherein the step (a) is performed by an optical sensor.

9. The illuminating method of claim 6, wherein the step (b) is performed by a comparison device.

10. The illuminating method of claim 6, wherein the step (c) is performed by a capacitive touch sensor.

11. The illuminating method of claim 6, wherein the step (c) is performed by a resistive touch sensor.

12. The illuminating method of claim 6, wherein the illumination module comprises a light-emitting diode.
